(19) United States
(12) Patent Application Publication
(10) Pub. No.: US 2015/0349712 A1
(43) Pub. Date: Dec. 3, 2015

(54) RECONFIGURABLE VARACTOR BANK FOR A VOLTAGE-CONTROLLED OSCILLATOR

(71) Applicant: QUALCOMM Incorporated, San Diego, CA (US)

(72) Inventors: Tsai-Pi HUNG, San Diego, CA (US); Gang ZHANG, San Diego, CA (US); Jae-Hong CHANG, San Diego, CA (US); Yung-Chung LO, San Diego, CA (US); Jianjun YU, San Diego, CA (US); Yuehai JIN, San Diego, CA (US)

(21) Appl. No.: 14/489,444

(22) Filed: Sep. 17, 2014

Related U.S. Application Data
(60) Provisional application No. 62/003,999, filed on May 28, 2014.

(51) Int. Cl. H03B 5/12

(52) U.S. Cl. CPC H03B 5/1265; H03B 5/1212

(57) ABSTRACT

Aspects of a reconfigurable varactor array for providing a capacitance to control an output frequency of a voltage-controlled oscillator are provided. The reconfigurable varactor array can be configured to provide a configurable capacitance. The reconfigurable varactor array can include a plurality of varactor cells connected in parallel. The reconfigurable varactor array can also include a control circuit configured to receive a control signal to select the configurable capacitance from the reconfigurable varactor array. The control circuit can include a plurality of switch groups. Each switch group can be separately connected to one varactor cell in the reconfigurable varactor array. The control signal from the control circuit can control operation of each switch group.

### CROSS-REFERENCE TO RELATED APPLICATION

This application claims the benefit of U.S. Provisional Application Ser. No. 62/003,999, entitled, “Reconfigurable Varactor Bank for a Voltage-Controlled Oscillator” and filed on May 28, 2014, which is expressly incorporated by reference herein in its entirety.

### TECHNICAL FIELD

Various exemplary embodiments disclosed herein relate generally to electronic circuits. In particular, various embodiments relate to control circuits for oscillators.

### BACKGROUND

Various electronic devices use oscillators, such as voltage-controlled oscillators (VCOs) to generate desired frequencies for various circuits. For example, wireless devices can employ VCOs to generate target frequencies that are used to modulate data for transmission and reception over specified carrier waves.

VCOs are regularly incorporated in phase-locked loop (PLL) circuits, which provide control signals for the VCO to produce output signals at a desired frequency and phase. In order to perform specific features—sub processes like phase modulation, temperature control, etc.—the VCO is tuned to specific voltages based on the process to be performed and the desired frequency range. In current systems, each process can use a specific bank of varactors (variable capacitance diode) to provide a specific capacitance to tune the VCO. In order to meet process-voltage-temperature (PVT) design margins, each varactor bank is usually built beyond the expected maximum capacitance of each process, with each varactor bank able to provide a capacitance beyond the expected maximum value.

While varactors enable multiple processes using the same VCO, the design margin considerations result in occupation of larger silicon area. Further, the multiple sets of varactor banks that are unused for other processes result in parasitic capacitance that impacts the tuning range of the VCO. The design choices involved with using multiple varactor banks also negatively-affects phase noise from the VCO. Issues with parasitic capacitance and phase noise are especially problematic when the VCO is operating at higher frequencies.

In view of the foregoing, it would be desirable to improve use of varactors in VCO tuning. In particular, it would be desirable to use varactors more effectively to improve the tuning range of VCOs in a circuit chip.

### SUMMARY

In light of the present need for an improved varactor bank for a voltage-controlled oscillator, a brief summary of various exemplary embodiments is presented. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in the later sections.

Aspects of a reconfigurable varactor array for providing a capacitance to control an output frequency of a voltage-controlled oscillator are provided. The reconfigurable varactor array can be configured to provide a configurable capacitance. The reconfigurable varactor array can include a plurality of varactor cells connected in parallel. The reconfigurable varactor array can also include a control circuit configured to receive a control signal to select the configurable capacitance from the reconfigurable varactor array. The control circuit can include a plurality of switch groups. Each switch group can be separately connected to one varactor cell in the reconfigurable varactor array. The control signal from the control circuit can control operation of each switch group.

It should be apparent that, in this manner, various exemplary embodiments enable an improved varactor bank. Particularly, by providing a single, reconfigurable varactor bank controlled using multiple switching groups, the reconfigurable varactor bank can provide the requisite capacitance while requiring lower total capacitance to adhere to design margin and using less silicon area on a circuit chip.

### BRIEF DESCRIPTION OF THE DRAWINGS

In order to better understand various exemplary embodiments, reference is made to the accompanying drawings wherein:

FIG. 1 illustrates a wireless device communicating with wireless communications systems;

FIG. 2 illustrates an exemplary wireless transceiver employing frequency synthesizers;

FIG. 3 illustrates an exemplary phase-looked loop circuit including the varactor bank;

FIG. 4 illustrates an exemplary stage of a phase-locked loop circuit including the varactor bank and VCO;

FIG. 5 illustrates an exemplary control circuit diagram for a varactor cell;

FIG. 6A illustrates an exemplary dual charge-pump circuit incorporating varactor bank controls;

FIG. 6B illustrates a portion of the dual charge-pump circuit incorporating varactor bank controls;

FIG. 6C illustrates another portion of the dual charge-pump circuit incorporating varactor bank controls;

FIG. 7 illustrates a comparison table of required capacitance for various varactor banks;

FIG. 8A illustrates a graph comparing threshold frequencies for a capacitance;

FIG. 8B illustrates a graph comparing frequency tuning range for a capacitance;

FIG. 9 illustrates an exemplary method for providing a reconfigurable varactor bank for a circuit chip; and

FIG. 10 illustrates an exemplary method for configuring a varactor bank for a chosen VCO process.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of various concepts. However, it will be apparent to those skilled in the art that the present invention may be practiced without these specific details. In some instances, well-known structures and components are shown in block diagram form in order to avoid obscuring such concepts. Acronyms and other descriptive terminology may be used merely for convenience and clarity and are not intended to limit the scope of the invention. The term “exemplary” is used herein to mean “serving as an example, instance, or illustration.” Any design described herein as “exemplary” is not necessarily to be construed as preferred or advantageous over other designs.

Several aspects of telecommunication systems will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise random-access memory (RAM), read-only memory (ROM), electronically erasable programmable ROM (EEPROM), compact disk (CD) ROM (CD-ROM), or other optical disk storage, magnetic disk storage or other magnetic storage devices, or any other medium that can be used to carry or store desired program code in the form of instructions or data structures and that can be accessed by a computer. Disk and disc, as used herein, includes CD, laser disc, optical disc, digital versatile disc (DVD), and floppy disk where disks usually reproduce data magnetically, while discs reproduce data optically with lasers. Combinations of the above should also be included within the scope of computer-readable media.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus, circuit or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the terms “comprises”, “comprising,”, “includes” and/or “including”, when used herein, specify the presence of the stated features, integers, steps, operations, elements, and/or components, but do not preclude the presence or addition of one or more other features, integers, steps, operations, elements, components, and/or groups thereof.

Various aspects of circuits for an optimized reconfigurable varactor will now be presented. However, as those skilled in the art will readily appreciate, such aspects may be extended to other circuit configurations and devices. Accordingly, all references to a specific application for VCO arrangements, or any component, structure, feature, functionality, or process within a synchronized wireless device are intended only to illustrate exemplary aspects of electronic hardware with the understanding that such aspects may have a wide differential of applications.

Various embodiments of hardware with an installed frequency divider may be used, such as a mobile phone, personal digital assistant (PDA), desktop computer, laptop computer, palm-sized computer, tablet computer, set-top box, navigation device, work station, game console, media player, or any other suitable device.

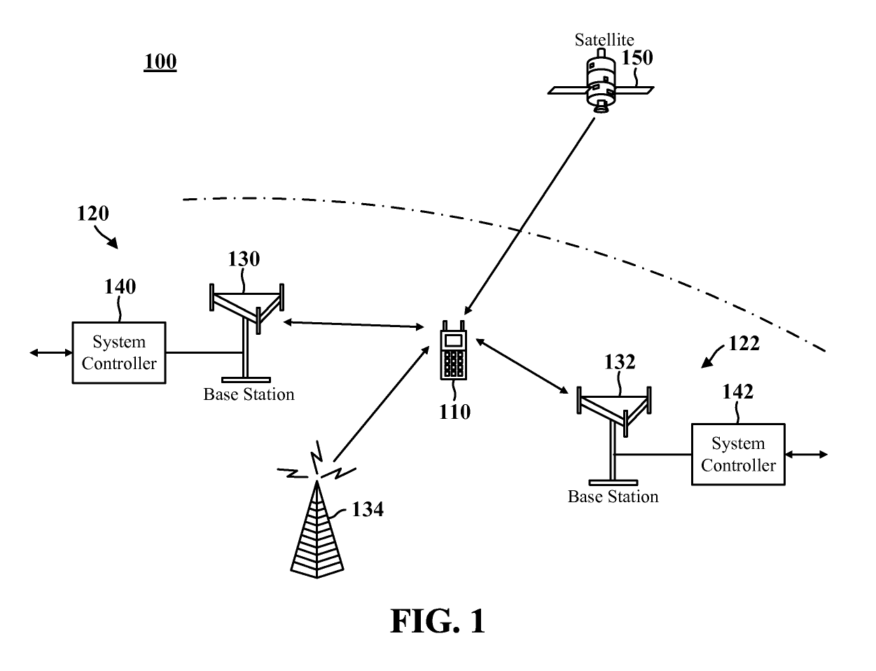

FIG. 1 illustrates a wireless device communicating with different wireless communications systems. FIG. 1 is a diagram 100 illustrating a wireless device 110 communicating with different wireless communication systems 120, 122. Wireless device 110 can use a VCO, for example, for communications via carrier waves at specified frequencies via techniques like phase modulation; other uses of VCOs in electronic hardware are known to those of skill in the art.

Wireless systems 120, 122 may each be a Code Division Multiple Access (CDMA) system, a Global System for Mobile Communications (GSM) system, a Long Term Evolution (LTE) system, a wireless local area network (WLAN) system, or some other wireless system. A CDMA system may implement Wideband CDMA (WCDMA), CDMA 1X or cdma2000, Time Division Synchronous Code Division Multiple Access (TD-SCDMA), or some other version of CDMA. TD-SCDMA is also referred to as Universal Terrestrial Radio Access (UTRA) Time Division Duplex (TDD) 1.28 Mcps Option or Low Chip Rate (LCR). LTE supports both frequency division duplexing (FDD) and time division duplexing (TDD). For example, wireless system 120 may be a GSM system, and the wireless system 122 may be a WCDMA system. As another example, the wireless system 120 may be an LTE system, and wireless system 122 may be a CDMA system.

For simplicity, diagram 100 shows wireless system 120 including one base station 130 and one system controller 140, and wireless system 122 including one base station 132 and one system controller 142. In general, each wireless system 120, 122 may include any number of base stations and any set of network entities. Each base station 130, 132 may support communication for wireless devices within the coverage of the base station. Base stations 130, 132 may also be referred to as a Node B, an evolved Node B (eNB), an access point, a base transceiver station, a radio base station, a radio transceiver, a transceiver function, a basic service set (BSS), an extended service set (ESS), or some other suitable terminology. Wireless device 110 may also be referred to as a user equipment (UE), a mobile device, a remote device, a wireless device, a wireless communications device, a station, a mobile station, a subscriber station, a mobile subscriber station, a terminal, a mobile terminal, a remote terminal, a wireless terminal, an access terminal, a client, a mobile client, a mobile unit, a subscriber unit, a wireless unit, a remote unit, a handset, a user agent, or some other suitable terminology. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, or some other similar functioning device.

Wireless device 110 may be capable of communicating with wireless system 120 and/or 122. Wireless device 110 may also be capable of receiving signals from broadcast stations, such as broadcast station 134. Wireless device 110 may also be capable of receiving signals from satellites, such as satellite 150, in one or more global navigation satellite systems (GNSS). Wireless device 110 may support one or more radio technologies for wireless communication such as GSM, WCDMA, cdma2000, LTE, 802.11, etc. The terms “radio technology,” “radio access technology,” “air interface,” and “standard” may be used interchangeably.

Wireless device 110 may communicate with a base station in a wireless system via the downlink and the uplink. The downlink (or forward link) refers to the communication link from the base station to the wireless device, and the uplink (or reverse link) refers to the communication link from the wireless device to the base station. A wireless system may utilize TDD and/or FDD. For TDD, the downlink and the uplink may share the same frequency, and downlink transmissions and uplink transmissions may be sent on the same frequency in different time periods. For FDD, the downlink and the uplink are allocated separate frequencies. Downlink transmissions may be sent on one frequency, and uplink transmissions may be sent on another frequency. Some exemplary radio technologies supporting TDD include GSM, LTE, and TD-SCDMA. Some exemplary radio technologies supporting FDD include WCDMA, cdma2000, and LTE.

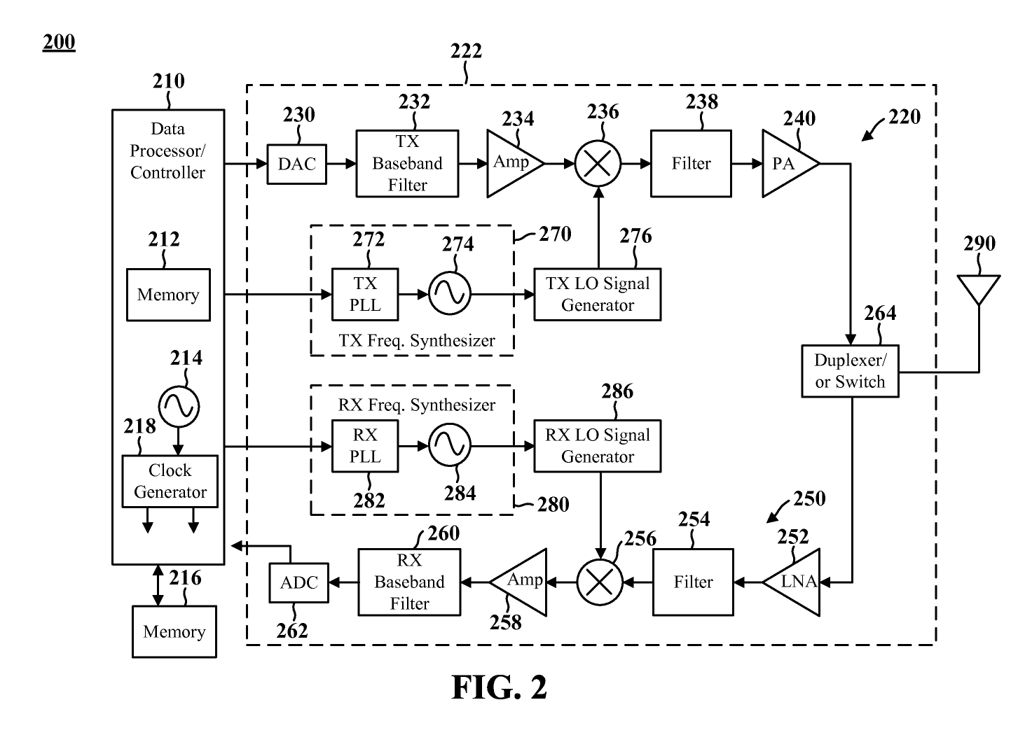

FIG. 2 is a block diagram 200 of an exemplary wireless device, such as the wireless device 110. The wireless device includes a data processor/controller 210, a transceiver 222, and an antenna 290. The data processor/controller 210 may be referred to as a processing system. A processing system may include the data processor/controller 210 or both the data processor/controller 210 and the memory 216. The transceiver 222 includes a transmitter 220 and a receiver 250 that support bi-directional communication. The transmitter 220 and/or the receiver 250 may be implemented with a super-heterodyne architecture or a direct-conversion architecture. In the super-heterodyne architecture, a signal is frequency converted between RF and baseband in multiple stages, e.g., from RF to an intermediate frequency (IF) in one stage, and then from IF to baseband in another stage for a receiver. In the direct-conversion architecture, which is also referred to as a zero-IF architecture, a signal is frequency converted between RF and baseband in one stage. The super-heterodyne and direct-conversion architectures may use different circuit blocks and/or have different requirements. In the exemplary design shown in FIG. 2, the transmitter 220 and the receiver 250 are implemented with the direct-conversion architecture.

In the transmit path, the data processor/controller 210 may process (e.g., encode and modulate) data to be transmitted and provide the data to a digital-to-analog converter (DAC) 230. The DAC 230 converts a digital input signal to an analog output signal. The analog output signal is provided to a transmit (TX) baseband (lowpass) filter 232, which may filter the analog output signal to remove images caused by the prior digital-to-analog conversion by the DAC 230. An amplifier (amp) 234 may amplify the signal from the TX baseband filter 232 and provide an amplified baseband signal. An upconverter (mixer) 236 may receive the amplified baseband signal and a TX LO signal from a TX LO signal generator 276. The upconverter 236 may upconvert the amplified baseband signal with the TX LO signal and provide an upconverted signal. A filter 238 may filter the upconverted signal to remove images caused by the frequency upconversion. A power amplifier (PA) 240 may amplify the filtered RF signal from the filter 238 to obtain the desired output power level and provide an output RF signal. The output RF signal may be routed through a duplexer/switchplexer 264.

For FDD, the transmitter 220 and the receiver 250 may be coupled to the duplexer 264, which may include a TX filter for the transmitter 220 and a receive (RX) filter for the receiver 250. The TX filter may filter the output RF signal to pass signal components in a transmit band and attenuate signal components in a receive band. For TDD, the transmitter 220 and the receiver 250 may be coupled to switchplexer 264. The switchplexer 264 may pass the output RF signal from the transmitter 220 to the antenna 290 during uplink time intervals. For both FDD and TDD, the duplexer/switchplexer 264 may provide the output RF signal to the antenna 290 for transmission via a wireless channel.

In the receive path, the antenna 290 may receive signals transmitted by base stations and/or other transmitter stations and may provide a received RF signal. The received RF signal may be routed through duplexer/switchplexer 264. For FDD, the RX filter within the duplexer 264 may filter the received RF signal to pass signal components in a receive band and attenuate signal components in the transmit band. For TDD, the switchplexer 264 may pass the received RF signal from the antenna 290 to the receiver 250 during downlink time intervals. For both FDD and TDD, the duplexer/switchplexer 264 may provide the received RF signal to the receiver 250.

Within the receiver 250, the received RF signal may be amplified by a low noise amplifier (LNA) 252 and filtered by a filter 254 to obtain an input RF signal. A downconverter (mixer) 256 may receive the input RF signal and an RX LO signal from an RX LO signal generator 286. The downconverter 256 may downconvert the input RF signal with the RX LO signal and provide a downconverted signal. The downconverted signal may be amplified by an amplifier 258 and further filtered by an RX baseband (lowpass) filter 260 to obtain an analog input signal. The analog input signal is provided to an analog-to-digital converter (ADC) 262. The ADC 262 converts an analog input signal to a digital output signal. The digital output signal is provided to the data processor/controller 210.

A TX frequency synthesizer 270 may include a TX phase locked loop (PLL) 272 and a VCO 274. The VCO 274 may generate a TX VCO signal at a desired frequency. The TX PLL 272 may receive timing information from the data processor/controller 210 and generate a control signal for the VCO 274. The control signal may adjust the frequency and/or the phase of the VCO 274 to obtain the desired frequency for the TX VCO signal. The TX frequency synthesizer 270 provides the TX VCO signal to the TX LO signal generator 276. The TX LO signal generator may generate a TX LO signal based on the TX VCO signal received from the TX frequency synthesizer 270.

A RX frequency synthesizer 280 may include an RX PLL 282 and a VCO 284. The VCO 284 may generate an RX VCO signal at a desired frequency. The RX PLL 282 may receive timing information from the data processor/controller 210 and generate a control signal for the VCO 284. The control signal may adjust the frequency and/or the phase of the VCO 284 to obtain the desired frequency for the RX VCO signal. The RX frequency synthesizer 280 provides the RX VCO signal to the RX LO signal generator 286. The RX LO signal generator may generate an RX LO signal based on the RX VCO signal received from the RX frequency synthesizer 280.

The LO signal generators 276, 286 may each include frequency dividers, buffers, etc. The LO signal generators 276, 286 may be referred to as frequency dividers if they divide a frequency provided by the TX frequency synthesizer 270 and the RX frequency synthesizer 280, respectively. The PLLs 272, 282 may each include a phase/frequency detector, a loop filter, a charge pump, a frequency divider, etc. Each VCO signal and each LO signal may be a periodic signal with a particular fundamental frequency. The TX LO signal and the RX LO signal from the LO generators 276, 286 may have the same frequency for TDD or different frequencies for FDD. The TX VCO signal and the RX VCO signal from the VCOs 274, 284 may have the same frequency (e.g., for TDD) or different frequencies (e.g., for FDD or TDD).

The conditioning of the signals in the transmitter 220 and the receiver 250 may be performed by one or more stages of amplifier, filter, upconverter, downconverter, etc. These circuits may be arranged differently from the configuration shown in FIG. 2. Furthermore, other circuits not shown in FIG. 2 may also be used to condition the signals in the transmitter 220 and the receiver 250. For example, impedance matching circuits may be located at the output of the PA 240, at the input of the LNA 252, between the antenna 290 and the duplexer/switchplexer 264, etc. Some circuits in FIG. 2 may also be omitted. For example, the filter 238 and/or the filter 254 may be omitted. All or a portion of the transceiver 222 may be implemented on one or more analog integrated circuits (ICs), RF ICs (RFICs), mixed-signal ICs, etc. For example, the TX baseband filter 232 to the PA 240 in the transmitter 220, the LNA 252 to the RX baseband filter 260 in the receiver 250, the PLLs 272, 282, the VCOs 274, 284, and the LO signal generators 276, 286 may be implemented on an RFIC. The PA 240 and possibly other circuits may also be implemented on a separate IC or a circuit module.

The data processor/controller 210 may perform various functions for the wireless device. For example, the data processor/controller 210 may perform processing for data being transmitted via the transmitter 220 and received via the receiver 250. The data processor/controller 210 may control the operation of various circuits within the transmitter 220 and the receiver 250. The memory 212 and/or the memory 216 may store program codes and data for the data processor/controller 210. The memory may be internal to the data processor/controller 210 (e.g., the memory 212) or external to the data processor/controller 210 (e.g., the memory 216). The memory may be referred to as a computer-readable medium. An oscillator 214 may generate a VCO signal at a particular frequency. A clock generator 218 may receive the VCO signal from the oscillator 214 and may generate clock signals for various modules within the data processor/controller 210. The data processor/controller 210 may be implemented on one or more application specific integrated circuits (ASICs) and/or other ICs.

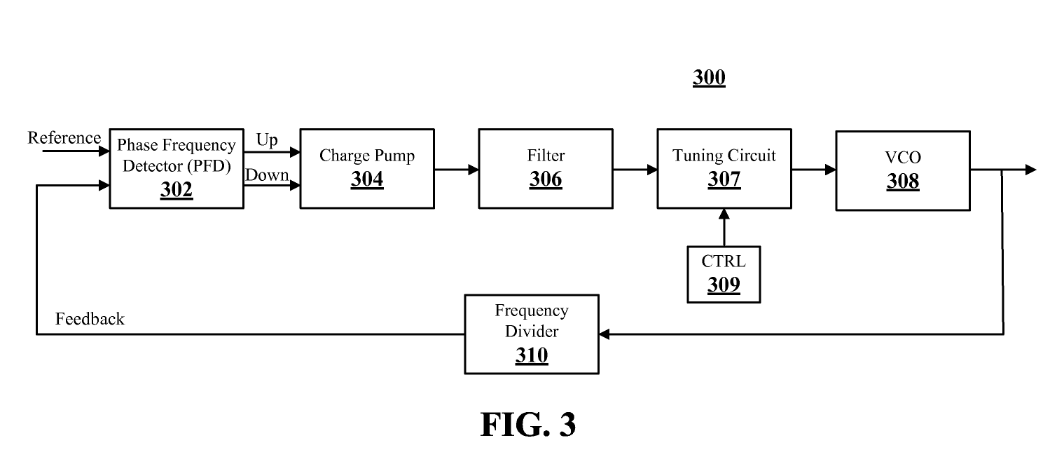

FIG. 3 illustrates an exemplary phase-looked loop circuit including the varactor bank. Phase-locked loop (PLL) 300 includes a phase-frequency detector (PFD) 302, a charge pump 304, a filter 306, a tuning circuit 307, a VCO 308, a control circuit 309, and a divider 310.

Phase-frequency detector 302 can, for example detect a phase difference between two input signals. In the illustrative embodiment, PFD 302 can be used to detect a phase error between a reference (input) signal and a feedback signal from divider 310. In some embodiments, the reference input signal can be received from oscillator 214. Phase frequency detector 302 generates UP and DOWN signals based on the phase error. The UP and DOWN signals are used to drive charge pump 304. Charge pump 304 can provide a current source to filter 306. Charge pump 304 injects a charge proportional to the detected phase error into the filter 306.

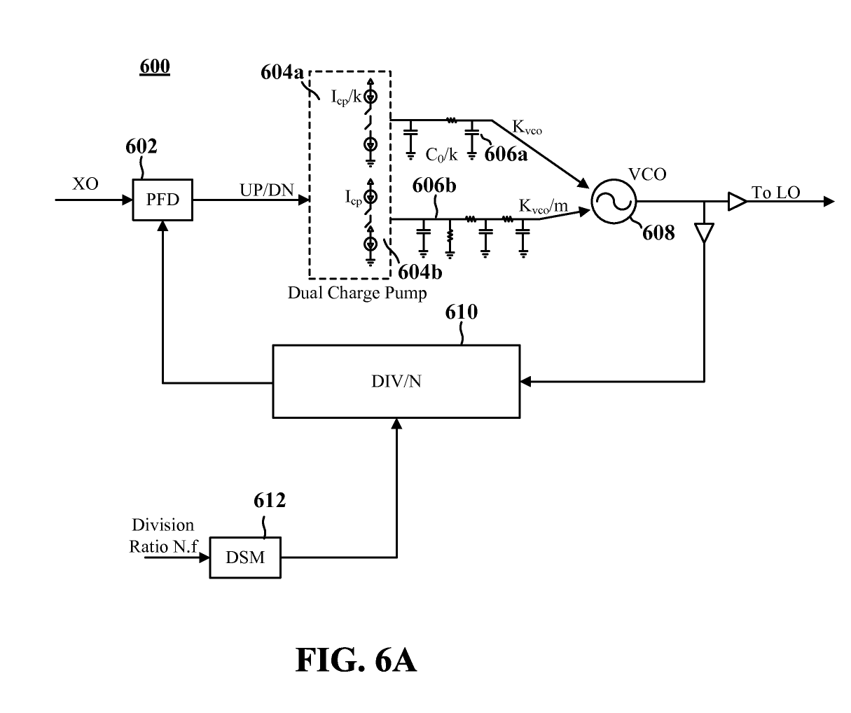

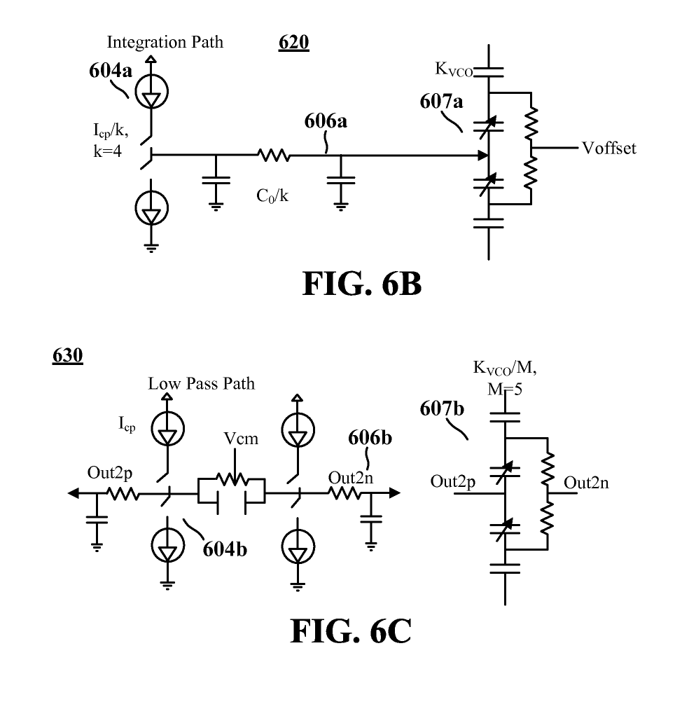

Filter 306 can generate a control voltage used for tuning VCO 308. Filter 306 can be a specific form of filter, such as a loop filter, that integrates the output from charge pump 304 to generate a control voltage that is input to tuning circuit 307 and VCO 308. As will be discussed in relation to FIGS. 6A-6C, in some embodiments, filter 306 can be a component of tuning circuit 307.

Tuning circuit 307 can receive the control voltage generated by filter 306 to produce a tuning capacitance that controls the output of VCO 308. In some embodiments, tuning circuit 307 can, in combination with VCO 308, form a tank circuit. In such instances, tuning circuit 307 and a capacitor in VCO 308 can be combined to provide a total capacitance that controls the output frequency of VCO 308.

In some embodiments, tuning circuit 307 can include one or more varactors that provide a specified capacitance. Tuning circuit 307 can include a reconfigurable varactor bank as an array of varactors or varactor cells that can provide a specified maximum capacitance. In some embodiments, tuning circuit 307 receives one or more control signals from control circuit 309 to produce the specified capacitance to the VCO based on the control voltage received from filter 306.

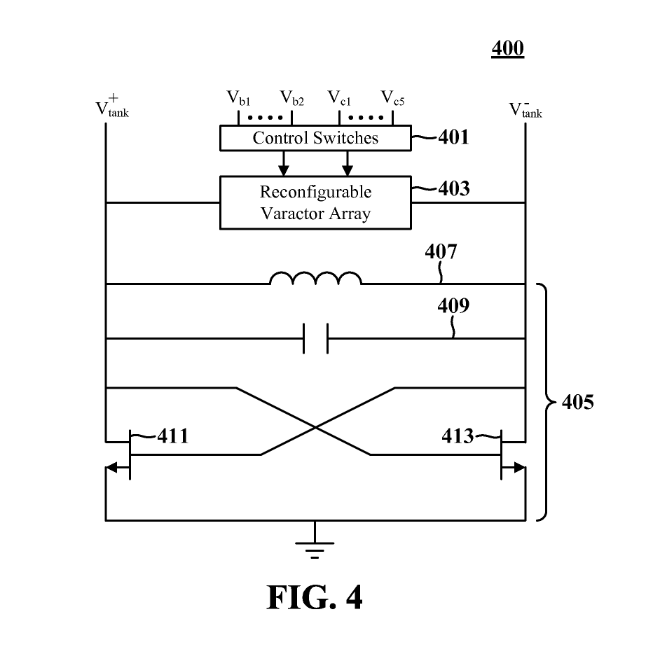

VCO 308 can generate an oscillating signal having a tunable frequency. VCO 308 can generate an oscillating signal whose frequency is proportional to the tuning voltage produced by tuning circuit 307. In some embodiments, the output frequency of VCO 308 can be derived from:

$${f}_{VCO} = \frac{1}{2 π \sqrt{LC}} \qquad ( 1 )$$

Where L is the inductance and C is the capacitance for an exemplary LC VCO (i.e., tank) circuit for VCO 308. As will be discussed in further detail in relation to FIG. 4, an array of varactor cells included in tuning circuit 307 can add to the total capacitance of the tank circuit for VCO 308. Modifying tuning circuit 307 alters the total capacitance of the tank circuit and alters the output frequency of VCO 308.

Control circuit 309 can produce one or more control signals to control components in tuning circuit 307 to produce the specified capacitance. In some embodiments, control circuit 309 may comprise processor/controller 210. In some embodiments, control circuit 309 can activate only a subset of varactors in tuning circuit 307. In such instances, the varactor array in tuning circuit 307 will provide a capacitance lower than the maximum capacitance of the varactor array. In some embodiments, the control signal can comprise bias voltages for the varactors in tuning circuit 307.

Frequency divider 310 can generate a feedback signal by fractionally dividing the frequency of the oscillating signal produced by VCO 308. Frequency divider 310 divides the frequency of the VCO output by an integer N to produce the feedback signal input to PFD 302.

FIG. 4 illustrates an exemplary stage of a phase-locked loop circuit including the varactor bank and the VCO. PLL stage 400 can comprise a tank circuit that includes control switches 401, reconfigurable varactor array 403, and an LC VCO 405. LC VCO 405 includes an inductor 407, a capacitor 409, and switches 411, 413. Varactors in reconfigurable varactor array 403 can, in conjunction with capacitor 409, modify the total capacitance of LC VCO 405.

As LC VCO 405 produces the target frequency as its resonant frequency (see e.g., equation (1) in relation to VCO 308 of FIG. 3), modifications to the total capacitance of tank circuit 400 modifies the resonant frequency (i.e., output frequency) of LC VCO 405. In the illustrative embodiment, the output frequency of LC VCO 405 can be a differential voltage as represented across LC VCO 405 as Vₜₐₙₖ⁺ and Vₜₐₙₖ⁻.

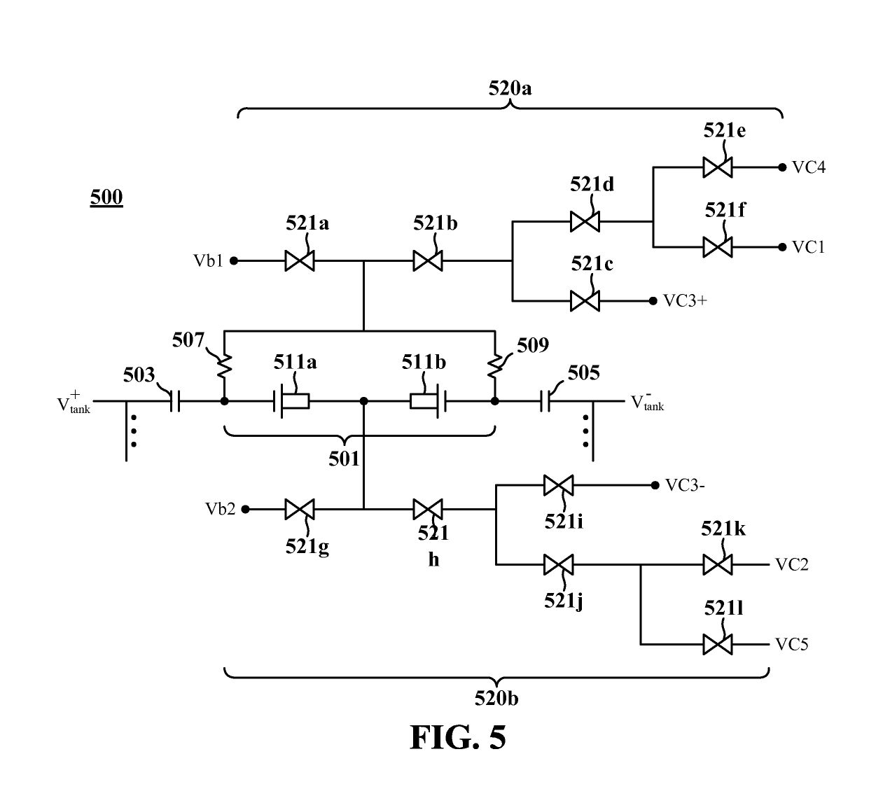

Control switches 401 can correspond to one or more switches in control circuit 309 that are used to configure the capacitance produced by reconfigurable varactor array 403. As will be discussed in relation to FIG. 5, control switches 401 can receive bias voltages as inputs and can be configured to connect to the ends of one or more varactors in reconfigurable varactor array 403. Control switches 401 can receive a control signal to close a specific arrangement of control switches such that a specified subset of varactor cells receives the bias voltages.

Reconfigurable varactor array 403 can be one or more varactor cells that can provide a desired capacitance for LC VCO 405. As each capacitance of each varactor is dependent upon the voltage placed across its terminals, the bias voltage it receives via control switches 401 can change the capacitance produced by reconfigurable varactor array 403, even if the same varactor cells are used with a different bias voltage to produce a different capacitance. In some embodiments, reconfigurable varactor array 403 may be configured to produce a maximum capacitance that is higher than a desired capacitance. In such instances, reconfigurable varactor array 403 can be controlled to use only a portion of its varactors to produce the desired capacitance for LC VCO 405.

FIG. 5 illustrates an exemplary control circuit diagram for a varactor cell. Reconfigurable varactor array 403 of FIG. 4 can comprise one or more varactor cells 501 connected in parallel; the plurality of varactor cells 501 in parallel can be configured to produce a capacitance up to the maximum capacitance of reconfigurable varactor array 403.

Control circuit 500 can be connected to each varactor cell 501 in reconfigurable varactor array 403 to provide specified bias voltages to specified groups of varactors 511a-b. Control circuit 500 includes switch groups 520a-b. Switch group 520a includes switches 521a-f and connects to positive terminals of varactors 511a-b via resistors 507, 509. Switch group 520b includes switches 521g-1. Varactor cell 501 includes varactors 511a-b. In some embodiments, the configuration of varactor cell 501 can be altered. For example, the illustrative embodiments has the negative terminals of varactors 511a-b connected, with switch group 520a connected to the positive terminals, while switch group 520b is connected to the negative terminals. Some embodiments can have a varactor cell 501 in reverse, with the positive terminals of varactors 511a-b connected, with switch group 520a connected to the positive terminals, while switch group 520b is connected to the negative terminals.

In some embodiments, varactor cell 501 can also include one or more AC-coupling capacitors 503, 505 connected to terminals of each varactor 511a-b. In some embodiments, AC-coupling capacitors 503, 505 can be connected to the positive terminals of varactor 511a-b. In other embodiments, AC-coupling capacitors 503, 505 can be connected to negative terminals of varactor 511a-b.

Switch groups 520a-b can be used to regulate the bias voltages received by varactor cell 501. Each varactor cell 501 in reconfigurable varactor array 403 can have independent switch groups 520a-b connected to it to regulate bias voltages for a particular varactor cell 501.

In some embodiments, control circuit 309 can receive a control signal that controls the state of each switch 521a-1 in switch groups 520a-b. In some embodiments, the control signal can be based on the desired process to be implemented. In such instances, a desired process will be associated with a specified set of bias voltages. For example, in the illustrative embodiment, tuning of the VCO's non-linear tuning sensitivity (“main KV”) can use vc1 (regulated by switches 521b, d, and f in switch group 520a) and vc2 (regulated by switches 521h, j, and k in switch group 520b) to bias varactor cell 501 of reconfigurable varactor bank 403. Bias voltages for other processes can be seen in Table 1. Bias voltages for other, non-listed processes can be supplied to bias varactor cell 501 in order for LC VCO 405 to produce a desired output frequency.

TABLE 1
Bias Voltages for VCO Processes

| | Positive Bias Voltage | Negative Bias Voltage |
|---|---|---|
| Process | (Switch Group 520a) | (Switch Group 520b) |
| K_{V} tuning | vc1 | vc2 |
| Temperature | vb1 | vb2 |
| Compensation | | |
| Differential Input Signal | vc3+ | vc3− |
| (e.g., Charge Pump) | | |
| Phase Modulation | vc4 | vc5 |

Depending on the bias voltage, varactor cell 501 can produce a different capacitance and thus produce a different frequency in VCO 308 or LC VCO 405. In some embodiments, one or more bias voltages are configured to produce the desired capacitance using each varactor cell 501 in reconfigurable varactor array 403. In some embodiments, one or more processes use fewer than the total array of varactor cells 501 in reconfigurable varactor array 403 to produce the desired capacitance.

FIG. 6A illustrates an exemplary dual charge-pump circuit incorporating varactor bank controls. PLL circuit 600 is an example of a circuit that employs a reconfigurable varactor array 607a-b. PLL circuit 600 includes PFD 602, dual charge pumps 604a-b, filters 606a-b, VCO 608, and frequency divider 610. As will be discussed in relation to FIGS. 6B-6C, PLL circuit 600 uses a reconfigurable varactor array illustrated as varactor cells 607a-b to receive control signal KVCO and proportional control signal KVCO/m. Frequency divider 610 can also receive a divider ratio from deep-sub micron (DSM) circuit 612.

In the illustrative embodiment, use of a reconfigurable varactor bank enables PLL circuits that use smaller capacitors to produce the desired control signals for VCO 608. For example, the capacitors used for filters 606a-b can be up to four times smaller than similar PLL circuits. PLL circuit 600 can use reconfigurable varactor array 403 to modify the total capacitance of VCO 608 to produce the desired output frequency.

FIG. 6B illustrates a portion of the dual charge-pump circuit incorporating varactor bank controls. Integration path 620 can be a portion of PLL circuit 600 and includes the charge pump 604a, the filter 606a, and a reconfigurable varactor array portion 607a. Reconfigurable varactor array portion 607a can receive as inputs the tuning signal KVCO from filter 606a and a specified offset (voffset).

FIG. 6C illustrates another portion of the dual charge-pump circuit incorporating varactor bank controls. Low-Pass Path 630 can be a portion of PLL circuit 600 and includes the charge pump 604b, the filter 606b, and reconfigurable varactor bank portion 607b. Reconfigurable varactor bank 603 can receive a differential input (out2n, out2p) produced by charge pump 604b and filters 606b that comprise the control signal KVCO/m. Reconfigurable varactor bank portions 607a-b of reconfigurable varactor bank 603 can use the two input control signals KVCO and KVCO/m to modify the output of VCO 608.

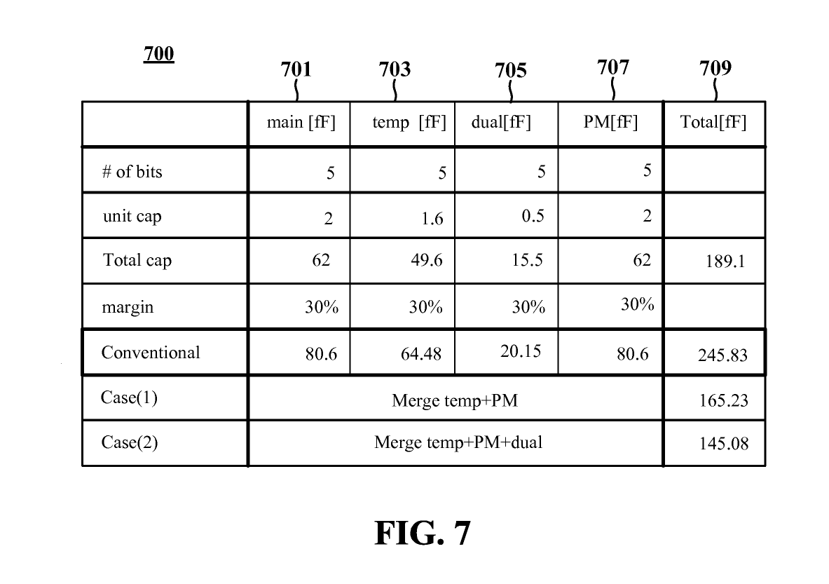

FIG. 7 is a comparison table of exemplary capacitance values for various varactor banks. Capacitance table 700 includes, for example, targets for total capacitance and design margin (i.e., capacitance overbuild) to be provided by varactor banks in order for a circuit to perform the desired processes under conventional conditions and when implementing various forms of reconfigurable varactor array 403. Table 700 includes Kv tuning (“main”) in column 701, temperature compensation (“temp”) in column 703, tuning using a differential input control signal (“dual”) in column 705, phase modulation (PM) in column 707, and total capacitance in column 709.

As seen in capacitance table 700, the total capacitance before considering design margin is 189.1 femtofarads (fF). Without reconfigurable varactor array 403, each varactor would be built separately. Using example design margin considerations (i.e., covering process variations) of a 30% overbuild in capacitance, a conventional circuit would require 245.83 fF. However, merging processes to use the same reconfigurable varactor array 403 lowers the total capacitance to be produced by reconfigurable varactor array 403. As seen in case (1), merging temp and PM processes to using a common reconfigurable varactor array 403 lowers the total capacitance to 165.23 fF. Similarly, for case (2), merging temp, PM, and dual processes in into a common reconfigurable varactor array 403 lowers the total capacitance to 145.08 fF, a 40% reduction in total capacitance to be produced by varactors in the circuit.

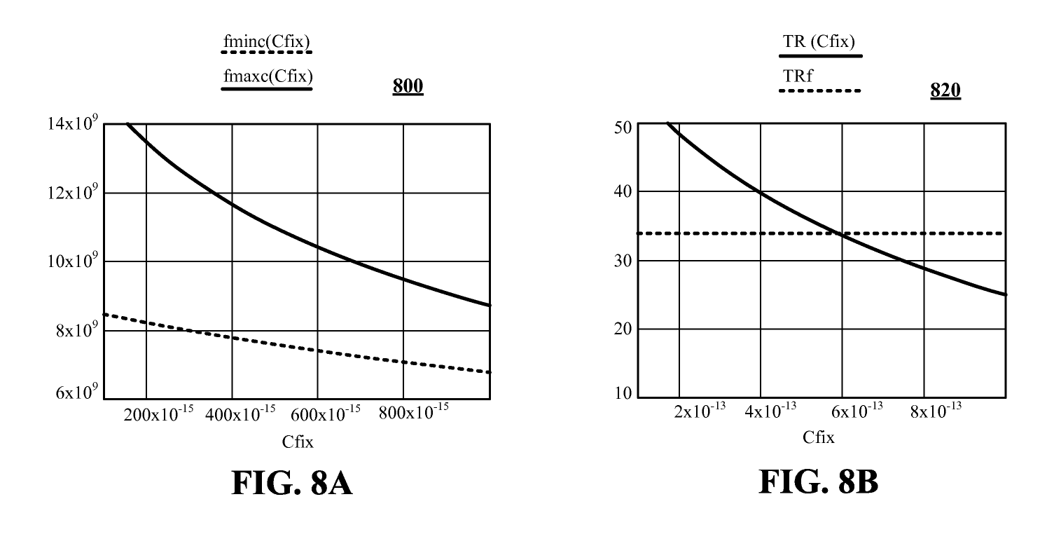

FIG. 8A illustrates a graph comparing threshold frequencies for a capacitance. Graph 800 illustrates the minimum and maximum frequencies produced by VCO 308 compared to the capacitance of the entire circuit (Cfix). In this embodiment, the total capacitance is directly correlated to the total capacitance of the reconfigurable varactor bank 403. FIG. 8B illustrates a graph comparing frequency tuning range for a capacitance. As shown by graph 820, the tuning range for PLL circuit 300 increases as the total capacitance for the circuit decreases. As reconfigurable varactor array 403 lowers the total capacitance, the tuning range for VCO 308 increases.

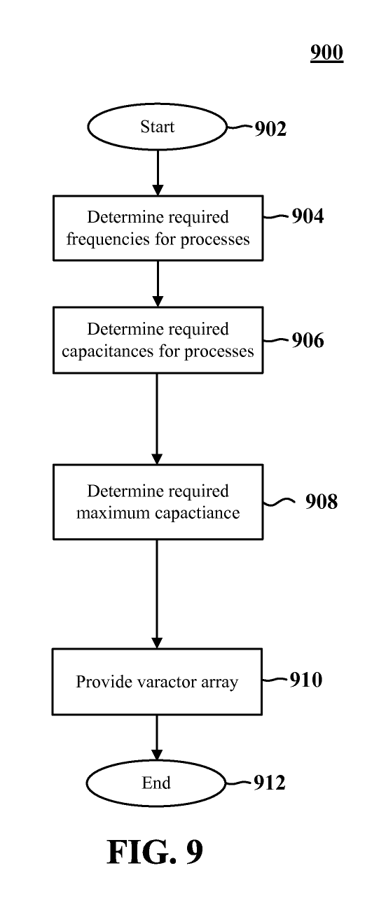

FIG. 9 illustrates an exemplary method for providing a reconfigurable varactor bank for a circuit chip. Method 900 can be performed when generating a PLL circuit 300 that includes a tuning circuit 307 comprising a reconfigurable varactor array 403. Method 900 can begin at step 902 and proceed to step 904, where a target VCO frequency is determined for at least one process. For example, a calibration circuit can determine desired target frequencies to be produced by VCO 308 when performing featured processes, such as Kv tuning. In some embodiments, the target determined frequency can be a frequency range, such as a desired range of frequencies to generate for phase modulation in TX/RX paths 220, 250.

After determining one or more target frequencies, method 900 can proceed to step 906, where a target capacitance for each process is determined. For example, a calibration circuit can determine a requisite capacitance for tank circuit 400 to produce the determined target frequency. In such instances, the capacitance determined can be a capacitance for reconfigurable varactor array 403 to be implemented in parallel with capacitor 409 to produce the desired LC frequency.

Once the desired capacitance for each process is determined, in step 908, the maximum capacitance required for tank circuit 400 can be determined by determining the largest required capacitance for each reconfigurable varactor array 403 to be used. For example, referring to capacitance table 700, in the case where two varactor arrays are implemented, one for main Kv tuning and one reconfigurable array for all the other processes, the required maximum capacitance is equal to the maximum capacitance for each reconfigurable varactor array 403 and is determined by adding the required capacitance for each array (e.g., 62 for main Kv and 49.6 for the shared varactor array) and determining the design margin capacitance (e.g., adding 30% to the maximum capacitance).

Once the required maximum capacitance is determined, method 900 can proceed to step 910, where at least one reconfigurable varactor array 403 is provided for PLL circuit 300. Once the reconfigurable varactor array 403 is provided, method 900 can end at step 912.

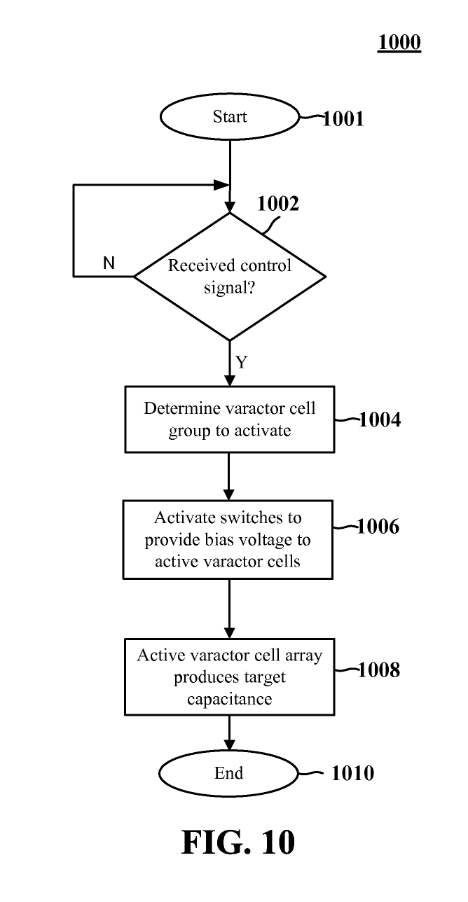

FIG. 10 illustrates an exemplary method for configuring a varactor bank for a chosen VCO process. Control circuit 309 can perform method 1000 via control switches 401, 520a-b to provide bias voltages to one or more varactor cells 501 in reconfigurable varactor array 403 to produce a desired capacitance. Method 1000 can start at step 1001 and proceed to step 1002, where control circuit 309 can determine whether it has received a control signal for switches 521a-1 in switch groups 520a-b. When control circuit 309 determines that it has received the control signal, control circuit 309 can proceed to step 1004, where control circuit 309 determines a group of varactor cells 501 in reconfigurable varactor array 403 to activate.

Once the specific varactor cells are identified in step 1004, control circuit in step 1006 can activate switches for the active varactor cells 501. For example, a process may use a subgroup of varactor cells to produce the desired capacitance. In such instance, only the switch groups 520a-b for the active varactor cells 501 would have their switches be active to provide a bias voltage to the connected, active varactor cell 501. Once the switches are active, reconfigurable varactor bank 403 in step 1008 produces the target capacitance for VCO 308 or LC VCO 405. Once the target capacitance is generated method 1000 can end at step 1010.

It is understood that the specific order or hierarchy of steps in the processes/flow charts disclosed is an illustration of exemplary approaches. Based upon design preferences, it is understood that the specific order or hierarchy of steps in the processes/flow charts may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. An apparatus for providing a capacitance, the apparatus comprising:
a reconfigurable varactor array configured to provide a configurable capacitance, the reconfigurable varactor array comprising:
a plurality of varactor cells, each varactor cell independently controlled and connected in parallel; and
a control circuit configured to receive control signals to select the configurable capacitance from the reconfigurable varactor array, the control circuit comprising:
a plurality of switch groups, each switch group separately connected to ends of one varactor cell in the reconfigurable varactor array, wherein the control signals independently control operation of each switch group to control each varactor cell independently.

2. The apparatus of claim 1, wherein each control signal comprises signals for switches in one of the plurality of switch groups to provide a bias voltage for each end of the varactor cell, the bias voltage controlling the configurable capacitance of the reconfigurable varactor array.

3. The apparatus of claim 2, wherein the bias voltage for the varactor cell is associated with a process from one of:
tuning a circuit based on a non-linear sensitivity of a voltage-controlled oscillator (Kᵥ);
compensating for a temperature of the circuit;
tuning an oscillator that receives a differential input signal; or
modulating a phase of an input signal.

4. The apparatus of claim 1, wherein the reconfigurable varactor array is configured to produce a target capacitance that modifies the output frequency a voltage-controlled oscillator (VCO).

5. The apparatus of claim 4, further comprising:
an LC VCO connected in parallel with the reconfigurable varactor array.

6. The apparatus of claim 1, wherein each varactor cell comprises:
a first varactor; and
a second varactor, a negative end of the first varactor being connected to a negative end of the second varactor.

7. The apparatus of claim 6, further comprising:
a first AC-coupling capacitor connected to a positive end of the first varactor; and
a second AC-coupling capacitor connected to a positive end of the second varactor.

8. The apparatus of claim 6, wherein:
a first portion of one of the plurality of switch groups is connected to the positive ends of the first and second varactors; and
a second portion of one of the plurality of switch groups is connected to negative ends of the first and second varactors.

9. The apparatus of claim 1, wherein each varactor cell comprises:
a first varactor; and
a second varactor, a positive end of the first varactor being connected to a positive end of the second varactor.

10. The apparatus of claim 9, further comprising:
a first AC-coupling capacitor connected to a negative end of the first varactor; and
a second AC-coupling capacitor connected to the negative end of the second varactor.

11. The apparatus of claim 4, wherein a subset of the plurality of varactor cells in the reconfigurable varactor array is configured to produce the target capacitance.

12. A method for providing a capacitance, the method comprising:
determining an output frequency to be produced by a voltage-controlled oscillator (VCO), the output frequency based on a specified process;
determining a capacitance that causes the VCO to produce the determined output frequency; and
providing a reconfigurable varactor array to provide the determined capacitance, the reconfigurable varactor array comprising:
a plurality of varactor cells, each varactor cell independently controlled and connected in parallel; and
a control circuit configured to receive control signals to select the determined capacitance from the reconfigurable varactor array, the control circuit comprising:
a plurality of switch groups, each switch group separately connected to ends of one varactor cell in the reconfigurable varactor array, wherein the control signals independently control operation of each switch group to control each varactor cell independently.

13. The method of claim 12, further comprising:
determining output frequencies to be produced by the VCO for each of a plurality of specified processes;
determining capacitances that cause the VCO to produce each of the determined output frequencies; and
determining a maximum capacitance from the plurality of determined capacitances, wherein the reconfigurable varactor array is configured to provide the maximum capacitance.

14. The method of claim 13, further comprising:
providing, by the reconfigurable varactor array, a capacitance for one of the plurality of specified processes, wherein a subset of varactor cells in the reconfigurable varactor array produces the determined capacitance.

15. The method of claim 12, wherein the specified process comprises one of:
tuning a circuit based on a non-linear sensitivity of a voltage-controlled oscillator (Kᵥ);
compensating for a temperature of the circuit;
tuning an oscillator that receives a differential input signal; or
modulating a phase of an input signal.

16. The method of claim 12, wherein the VCO comprises an LC VCO connected in parallel with the reconfigurable varactor array.

17. A method of providing an output frequency of a voltage-controlled oscillator (VCO), the method comprising:
receiving, by a reconfigurable varactor array, control signals to provide a configurable capacitance, the reconfigurable varactor array comprising:
a plurality of varactor cells, each varactor cell independently controlled and connected in parallel; and
a control circuit configured to receive the control signals to provide the configurable capacitance from the reconfigurable varactor array, the control circuit comprising:
a plurality of switch groups, each switch group separately connected to ends of one varactor cell in the reconfigurable varactor array, wherein the control signals independently control operation of each switch group to control each varactor cell independently;
selecting at least one varactor cell in the reconfigurable varactor array to provide the configurable capacitance;
activating a switch group associated with the at least one selected varactor cell to provide a bias voltage to the at least one selected varactor cell;
providing, by the at least one selected varactor cell, the configurable capacitance to the VCO; and
producing, by the VCO, the output frequency based on the configurable capacitance provided by the reconfigurable varactor array.

18. The method of claim 17, wherein the configurable capacitance is the maximum capacitance of the reconfigurable varactor array.

19. The method of claim 17, wherein the VCO comprises an LC VCO connected in parallel with the reconfigurable varactor array.

20. The method of claim 17, wherein a subset of the plurality of varactor cells in the reconfigurable varactor array produce a target capacitance.
